(19) United States
(12) Patent Application Publication
(10) Pub. No.: US 2025/0079235 A1
(43) Pub. Date: Mar. 6, 2025

(54) WAFER SUPPORT TABLE AND RF ROD

(71) Applicant: NGK INSULATORS, LTD., Nagoya-City (JP)

(72) Inventor: Tomohiro HARA, Handa-City (JP)

(73) Assignee: NGK INSULATORS, LTD., Nagoya-City (JP)

(21) Appl. No.: 18/933,053

(22) Filed: Oct. 31, 2024

Related U.S. Application Data
(63) Continuation of application No. PCT/JP2023/032112, filed on Sep. 1, 2023.

(51) Int. Cl. H01L 21/687; H01J 37/32

(52) U.S. Cl. CPC H01L 21/68785; H01L 21/68757; H01J 37/32082; H01J 37/32724

(57) ABSTRACT

A wafer support table includes a ceramic base having a wafer placement surface and including an RF electrode and a heater electrode embedded; a hole extending from a surface of the ceramic base opposite the wafer placement surface toward the RF electrode; and an RF rod having a top end joined to the RF electrode exposed to a bottom of the hole or joined to a conductive member connected to the RF electrode; wherein the RF rod is a hybrid rod including a first rod member that is made of Ni and constitutes a portion of the RF rod from the top end to a predetermined position and a second rod member that is joined to the first rod member and constitutes a portion of the RF rod from the predetermined position to the base end, and the second rod member is a non-magnetic core member with an oxidation-resistant film.

### BACKGROUND OF THE INVENTION

### 1. Field of the Invention

The present invention relates to a wafer support table and an RF rod.

### 2. Description of the Related Art

A known ceramic wafer support table that is used, for example, to form a film on a wafer by plasma CVD has an RF rod connected to an RF electrode embedded in the ceramic base. For example, PTL 1 describes a hybrid rod as an RF rod. The RF rod is composed of a first rod member that is made of Ni and constitutes a portion from a top end to a predetermined position and a second rod member that is made of a non-magnetic material (e.g., tungsten) and constitutes a portion from the predetermined position to a base end of the RF rod. In this way, it is possible to prevent an area directly above the RF rod from an excessively high temperature.

### CITATION LIST

### Patent Literature

PTL 1: JP 7129587 B

### SUMMARY OF THE INVENTION

However, in an oxidizing environment, a surface of the second rod member made of non-magnetic material could be oxidized. When the surface of the second rod member is oxidized, the oxidized portion may be peeled off, and the second rod member may be gradually thinned and have been damaged.

The present invention is made to solve the above-described problem, and a main object of the invention is to prevent an area directly above the RF rod from an excessively high temperature and a deterioration due to oxidation even in an oxidizing environment.
[1] A wafer support table according to the present invention includes: a ceramic base having a wafer placement surface and including an RF electrode and a heater electrode embedded; a hole extending from a surface of the ceramic base opposite the wafer placement surface toward the RF electrode; and an RF rod through which radio-frequency power is supplied to the RF electrode and having a top end joined to the RF electrode exposed to a bottom of the hole or joined to a conductive member connected to the RF electrode, wherein the RF rod is a hybrid rod including a first rod member that is made of Ni and constitutes a portion of the RF rod from the top end to a predetermined position located between the top end and a base end and a second rod member that is joined to the first rod member and constitutes a portion of the RF rod from the predetermined position to the base end, and the second rod member is a non-magnetic core member with an oxidation-resistant film around the non-magnetic core member.

In the wafer support table according to the present invention, the second rod member is a non-magnetic core member with an oxidation-resistant film around it. Therefore, it is less likely to produce heat and to be heated to a high temperature by radio-frequency power supplied thereto than a second rod member made of Ni. Therefore, the overall RF rod is less likely to be heated to a high temperature and does not prevent heat release from the ceramic base. As a result, a temperature of a portion of the wafer directly above the rod connected to the RF electrode can be prevented from becoming excessively high. Furthermore, since the second rod member has the oxidation-resistant film around the non-magnetic core member, deterioration due to oxidation of the second rod member can be suppressed even in an oxidizing environment where the non-magnetic core member is oxidized.
[2] In the wafer support table according to the present invention (the wafer support table according to the above [1]), the predetermined position is determined by using a rod made of Ni, instead of the hybrid rod, and is a position where T(x) represented by T(x)=Ts−(ΔT/L)*x is greater than or equal to the Curie temperature of Ni and lower than or equal to the oxidation temperature of the non-magnetic core member, where Ts [° C] is a temperature of the heater electrode (provided that Ts exceeds the Curie temperature of Ni), L [cm] is a length of the rod made of Ni, ΔT [° C.] is a difference in temperature between ends of the rod made of Ni, x [cm] is a length of the rod made of Ni from the top end to the predetermined position, and T(x) [° C.] is a temperature of the rod made of Ni at the predetermined position. The portion from the top end to the predetermined position determined as above, or the first rod member, is made of Ni and is not magnetic at the Curie temperature or above, reducing an increase in impedance. The portion from the predetermined position determined as above to the base end, or the second rod member, is the non-magnetic core member with the oxidation-resistant film around it, reducing an increase in impedance. Furthermore, the temperature is lower than or equal to the oxidation temperature of the non-magnetic core member, preventing oxidization of the second rod member.
[3] In the wafer support table according to the present invention (the wafer support table according to the above [1] or [2]), the non-magnetic core member may be a tungsten core member and the oxidation-resistant film may be a tungsten carbide film. In this configuration, the second rod member can be manufactured relatively easily. In other words, it is relatively easy to form an oxidation-resistant film of tungsten carbide by carburizing or applying PVD or CVD around the tungsten core member. Since the hardness of tungsten carbide is higher than that of tungsten, the surface of the second rod member is not easily scratched even if the number of times the second rod member is inserted or removed from an external socket may increase.
[4] In the wafer support table according to the present invention (the wafer support table according to the above [3]), the thickness of the tungsten carbide film may be greater than or equal to 0.1 μm and less than or equal to 5 μm. If the thickness of the tungsten carbide film is greater than or equal to 0.1 μm, oxidation and damage of the tungsten core member can be sufficiently prevented. Although the electrical resistivity of tungsten carbide is higher than that of tungsten, if the thickness of the tungsten carbide film is less than or equal to 5 μm, the tungsten carbide film does not significantly affect an electrical conductivity of the second rod member.

An RF rod according to the present invention is a hybrid rod and includes: a first rod member that is made of Ni and constitutes a portion from a top end to a predetermined position located between the top end and a base end and a second rod member that is joined to the first rod member and constitutes a portion from the predetermined position to the base end, wherein the second rod member is a non-magnetic core member with an oxidation-resistant film around the non-magnetic core member.

It is highly worth applying this RF rod to the wafer support table of the present invention (the wafer support table according to the above [1]-[5]).

### BRIEF DESCRIPTION OF THE DRAWINGS

FIG. 1 is a perspective view of a plasma generator 10.

FIG. 2 is a sectional view taken along line A-A in FIG. 1.

FIG. 3 is a sectional view of an RF rod 30 taken in the longitudinal direction.

FIG. 4 is a sectional view taken along line B-B in FIG. 1.

FIG. 5 is a view for explaining how a predetermined position 33 is determined.

FIG. 6 is a view for explaining how the predetermined position 33 is determined.

FIG. 7 is a sectional view illustrating how a conductive member 23 and the RF rod 30 are joined together.

### DETAILED DESCRIPTION OF THE INVENTION

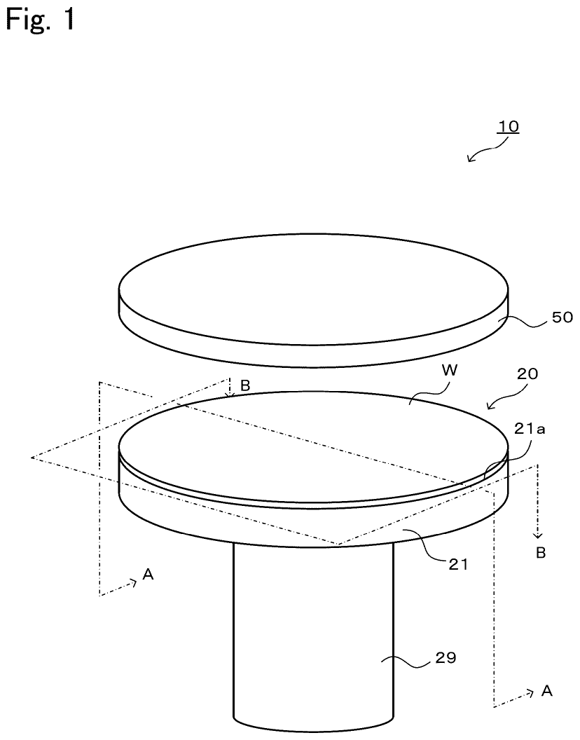

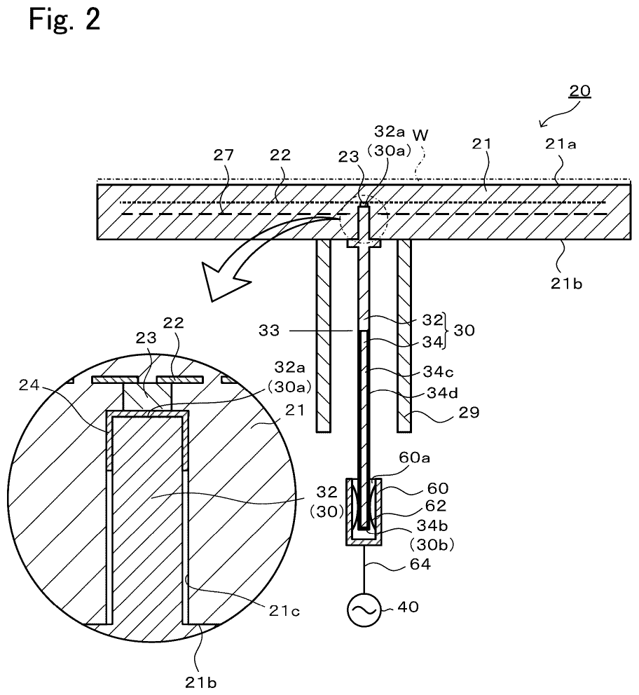

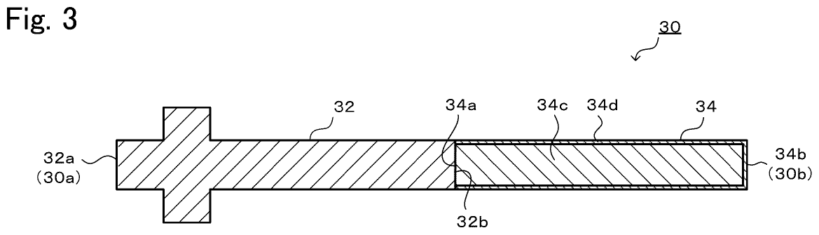

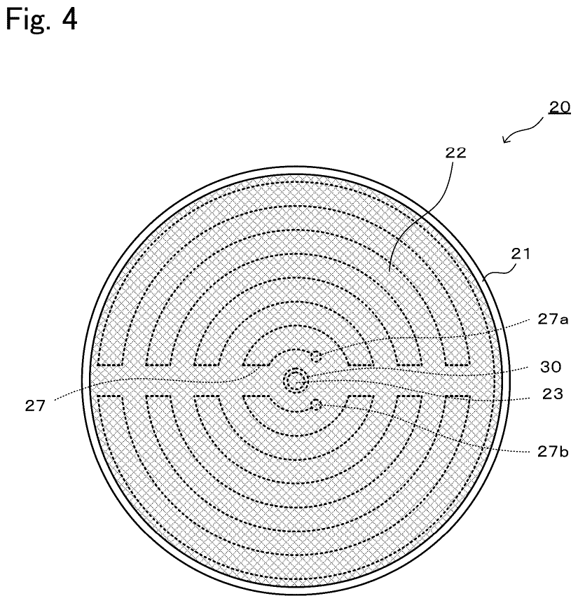

A preferred embodiment of the present invention will be described below with reference to the drawings. FIG. 1 is a perspective view of a plasma generator 10, FIG. 2 is a sectional view taken along line A-A in FIG. 1, FIG. 3 is a sectional view of an RF rod 30 taken in the longitudinal direction, and FIG. 4 is a sectional view taken along line B-B in FIG. 1.

As illustrated in FIG. 1, the plasma generator 10 includes a wafer support table 20 and an upper electrode 50.

The wafer support table 20 is used to support and heat a wafer W on which CVD or etching is performed with plasma. The wafer support table 20 is mounted in a semiconductor processing chamber (not illustrated). The wafer support table 20 includes a ceramic base 21 and a ceramic shaft 29 that is a hollow member.

The ceramic base 21 is a disc-like component made of ceramic (here, aluminum nitride). The ceramic base 21 has a wafer placement surface 21a on which a wafer W can be placed. The ceramic shaft 29 is attached to a middle of a surface (rear surface) 21b opposite the wafer placement surface 21a of the ceramic base 21. As illustrated in FIG. 2, an RF electrode 22 and a heater electrode 27 are embedded in the ceramic base 21 with a space therebetween. The RF electrode 22 and the heater electrode 27 are parallel (including substantially parallel, the same applies hereinafter) to the wafer placement surface 21a and the RF electrode 22 is closer to the wafer placement surface 21a. The ceramic base 21 has a hole 21c extending from the rear surface 21b toward the RF electrode 22. The conductive member 23 connected to the RF electrode 22 is exposed to the bottom of the hole 21c.

The RF electrode 22 is a disc-like thin-layer electrode having a slightly smaller diameter than the ceramic base 21 and is a mesh sheet made of woven thin metal wires composed mainly of Mo. The conductive member 23 having a disc-like shape is electrically connected to a substantially middle of the RF electrode 22. The conductive member 23 is exposed to the bottom of the hole 21c opening in the rear surface 21b of the ceramic base 21. The material of the conductive member 23 is Mo, which is the same as the RF electrode 22.

The heater electrode 27 is a coil composed mainly of Mo and arranged over the entire surface of the ceramic base 21 in a one-stroke pattern. Heater rods (not illustrated) are connected to respective ends 27a and 27b (see FIG. 4) of the heater electrode 27. The heater rods are connected to an external power source (not illustrated) through the inner space of the ceramic shaft 29.

The RF electrode 22, the conductive member 23, and the heater electrode 27 are made of Mo, because the thermal expansion coefficient thereof is close to that of the material of the ceramic base 21 (here, AlN) and thus a crack is less likely to be generated during production of the ceramic base 21. The RF electrode 22, the conductive member 23, and the heater electrode 27 may be made of any material that has a thermal expansion coefficient closer to that of AlN, instead of Mo. A thermocouple (not illustrated) is inserted into an area of the rear surface 21b of the ceramic base 21 surrounded by the ceramic shaft 29 to measure the temperature of the ceramic base 21.

The ceramic shaft 29 is a cylindrical component made of the same ceramic as the ceramic base 21. The upper end face of the ceramic shaft 29 is attached to the rear surface 21b of the ceramic base 21 by diffusion bonding or thermal compression bonding (TCB). TCB is a known technique including inserting a metal joint member between two components to be joined and pressure bonding the two components while heating to a temperature lower than or equal to the solidus temperature of the metal joint member.

The RF rod 30 is a solid cylindrical hybrid rod including a first rod member 32 that forms a portion of the RF rod 30 from a top end 30a to a predetermined position 33 located between the top end 30a and a base end 30b and a second rod member 34 that is joined to the first rod member 32 and forms a portion of the RF rod 30 from the predetermined position 33 to the base end 30b. How to determine the predetermined position 33 will be described later. The first rod member 32 is a bar-like component made of Ni. The second rod member 34 is a non-magnetic core member 34c having a lower impedance than Ni with an oxidation-resistant film 34d around the non-magnetic core member 34c. The oxidation-resistant film 34d is provided on the base end 34b (i.e., the base end 30b of the RF rod 30) but is not provided on a joining surface 34a of the second member 34. In this embodiment, the non-magnetic core member 34c is a tungsten rod member and the oxidation-resistant film 34d is a tungsten carbide film. The tungsten carbide film can be formed by carburizing or PVD on the tungsten rod member. The electrical resistivity of tungsten is 5.28×10⁻⁸ Ω·m, the electrical resistivity of tungsten carbide is 1.92×10⁻⁷ Ω·m, the Mohs hardness of tungsten is 7.5, and the Mohs hardness of tungsten carbide is 9. The joining surface 32b of the first rod member 32 and the joining surface 34a of the second rod member 34 may be welded or joined with a brazing material. For welding, butt welding can be used, for example, and as a soldering material, Ni soldering material can be used, for example.

The top end 30a of the RF rod 30 (i.e., the top end 32a of the first rod member 32) is joined to the conductive member 23 of the RF electrode 22 via a brazed portion 24, as shown in FIG. 2. The base end 30b of the RF rod 30 (i.e., the base end 34b of the second rod member 34) is connected to an RF power source 40 via a socket 60 and a cable 64. RF power from the RF power source 40 is supplied to the RF electrode 22 via the cable 64, the socket 60 and the RF rod 30. The socket 60 is a conductive closed-end cylinder. A spring 62 is disposed in the cylindrical interior space 60a of the socket 60. The spring 62 is cylindrical in shape with a narrowed center. The upper and lower diameters of the spring 62 match the diameter of the interior space 60a of the socket 60, and the diameter of the center of the spring 62 is smaller than the diameter of the interior space 60a of the socket 60. The side of the spring 62 has a plurality of slits extending in the vertical direction. The diameter of the second rod member 34 of the RF rod 30 is smaller than the diameter of the top of the spring 62 and larger than the diameter of the center of the spring 62. Therefore, when the second rod member 34 is inserted into the spring 62, the side of the spring 62 is elastically deformed and strongly contact the second rod member 34.

As illustrated in FIG. 1, the upper electrode 50 is fixed to a position above the wafer placement surface 21a (for example, a ceiling surface of a chamber (not illustrated)) and faces the wafer placement surface 21a of the ceramic base 21. The upper electrode 50 is grounded.

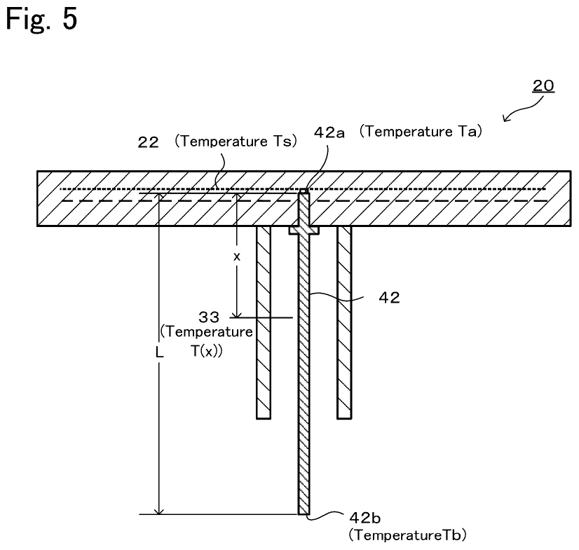

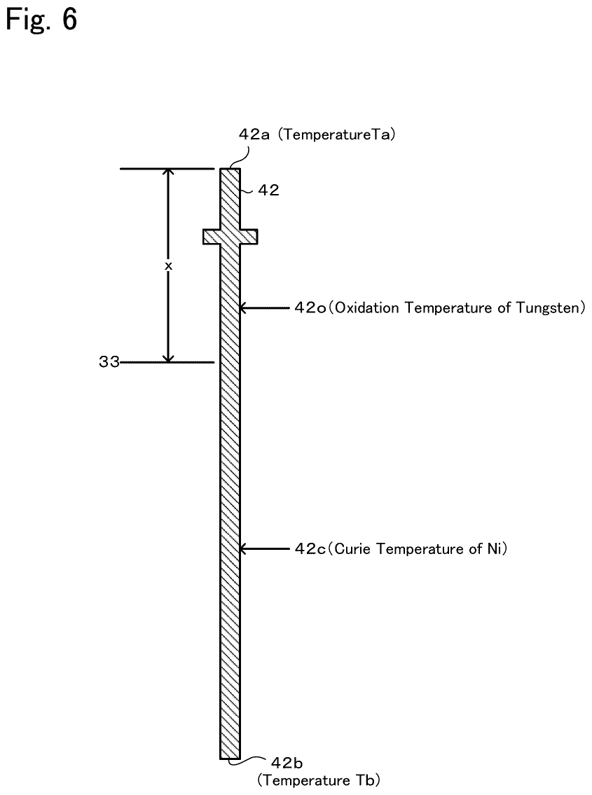

Here, the predetermined position 33 is determined as described below. As illustrated in FIG. 5, instead of the RF rod 30 (hybrid rod), a rod 42 made of Ni is attached to the wafer support table 20. Then, let the temperature of the heater electrode 27 be Ts [° C.] (provided that Ts is a temperature above the Curie temperature of Ni), the length of the rod 42 made of Ni be L [cm], a difference between the temperature Ta of the top end 42a and the temperature Tb of the base end 42b of the rod 42 made of Ni be ΔT(=Ta−Tb) [° C.], the length from the top end 42a (a portion connected to the RF electrode 22) to the predetermined position 33 of the rod 42 made of Ni be x [cm], and the temperature at the predetermined position 33 of the rod 42 made of Ni be T(x) [° C.]. Here, x [cm] is determined such that T(x) represented by formula (1) below becomes greater than or equal to 360° C., which is the Curie temperature of Ni, and lower than or equal to 400° C., which is the oxidation temperature of tungsten. Specifically described, as illustrated in FIG. 6, the length x [cm] from the top end 42a is determined such that the predetermined position 33 is located between a first position 42c where the temperature of the rod 42 made of Ni corresponds to the Curie temperature (360° C.) of Ni and a second position 420 where the temperature of the rod 42 made of Ni corresponds to the oxidation temperature (400° C.) of tungsten. The temperature Ta of the top end 42a of the rod 42 made of Ni is considered as substantially the same as the temperature Ts of the heater electrode 27.

T(x)=Ts−(ΔT/L)*x (1)

Next, an example of how the plasma generator 10 is used is explained. The plasma generator 10 is positioned in a chamber (not illustrated) and a wafer W is placed on the wafer placement surface 21a. Then, a reaction gas is introduced into the chamber and the RF power source 40 supplies a radio-frequency power (for example, 13 to 30 MHz) to the RF electrode 22. This generates plasma between parallel plate electrodes composed of the upper electrode 50 and the RF electrode 22 embedded in the ceramic base 21, enabling CVD film formation and etching on the wafer W with plasma. Furthermore, the temperature of the wafer W is determined by using a detection signal from a thermocouple (not illustrated), and the voltage applied to the heater electrode 27 is controlled such that the temperature becomes the set temperature (for example, 450° C., 500° C., or 550° C.). In this embodiment, regarding to the second core member 34 of the RF rod 30, the core member 34c is a tungsten core member and the oxidation-resistant film 34d is a tungsten carbide film. In this configuration, when the second rod member 34 is heated by the heat transferred from the first rod member 32, the second rod member 34 is less likely to be oxidized than one made of Cu, for example.

Furthermore, the RF rod 30 of this embodiment includes the first rod member 32 made of Ni as a portion to be in a temperature range above the Curie temperature of Ni. In such a temperature range, the first rod member 32 is not magnetic, reducing an increase in impedance. Furthermore, if the entire RF rod 30 is made of tungsten, an increase in impedance can be reduced, but the RF rod 30 would be oxidized at 400° C. or above. In contrast, the RF rod 30 according to this embodiment includes the second rod member 34 having a non-magnetic core member 34c as a portion to be in a temperature range below the oxidation temperature of tungsten. In such a temperature range, the core rod member 34c of the second rod member 34 is not oxidized, reducing oxidation of the second rod member 34. Because the second rod member 34 is a non-magnetic core member 34c with an oxidation-resistant film 34d around it, an oxidation of the second rod member 34 can be suppressed even in an oxidizing environment that the core rod member 34c is oxidized.

Next, an example of how the wafer support table 20 is produced is explained. First, a mold casting process is performed to form a ceramic molded article in which the RF electrode 22, the conductive member 23 having a surface in contact with the RF electrode 22 and the heater electrode 27 are embedded. Here, the “mold casting process” is a process of forming a molded article by injecting a ceramic slurry that contains ceramic material powder and a molding agent into a molding die and causing a chemical reaction of the molding agent in the molding die to mold the ceramic slurry. Next, the ceramic molded article is subjected to hot press sintering to obtain the ceramic base 21. Next, a grinding process is performed to form holes, such as a hole 21c in the rear surface 21b of the ceramic base 21 to which a surface of the conductive member 23 opposite the surface in contact with the RF electrode 22 is exposed, a hole for receiving a heater rod to be connected to the heater electrode 27, and a hole for receiving the thermocouple. Next, the ceramic shaft 29 is joined to the rear surface 21b of the ceramic base 21 by TCB with the ceramic base 21 and the ceramic shaft 29 being coaxial. Next, the conductive member 23 and the RF rod 30 are brazed. Then, the heater electrode 27 and the heater rod are joined together, and the thermocouple is attached, to produce the wafer support table 20.

In the wafer support table 20 described in detail above, the core member 34c of the second rod member 34 is made of tungsten and thus is less likely to produce heat and less likely to be heated to a high temperature by radio-frequency power supplied thereto than a second rod member 34 made of Ni. Thus, the entire RF rod 30 is less likely to be heated to a high temperature and does not prevent heat release from the ceramic base 21. As a result, a temperature of a portion of the wafer W directly above the RF rod 30 connected to the RF electrode 22 can be prevented from becoming excessively high. Furthermore, a deterioration due to oxidation of the second rod member can be suppressed even in an oxidizing environment (e.g., the environment exceeding the oxidation temperature of tungsten) because the second rod member 34 is the non-magnetic core member 34c with the oxidation-resistant film 34d around it.

Furthermore, the predetermined position 33 is determined by using a rod 42 made of Ni, instead of the RF rod 30 (hybrid rod), and is a position where T(x) represented by T(x)=Ts−(ΔT/L)*x is greater than or equal to the Curie temperature of Ni and lower than or equal to the oxidation temperature of the non-magnetic material (in this embodiment, tungsten), where Ts [° C.] is a temperature of the heater electrode 27 (provided that Ts exceeds the Curie temperature of Ni), L [cm] is a length of the rod 42 made of Ni, ΔT [° C.] is a difference in temperature between ends of the rod 42 made of Ni, x [cm] is a length of the rod 42 made of Ni from the top end 42a to the predetermined position 33, and T(x) [° C.] is a temperature of the rod 42 made of Ni at the predetermined position 33. Since the portion of the RF rod 30 from the top end 30a to the predetermined position 33 determined as above, that is the first rod member 32, is made of Ni and is not magnetic at the Curie temperature or above, an increase in impedance can be suppressed. Since the portion from the predetermined position 33 determined as above to the base end 30b, that is the second rod member 34, is the tungsten core member 34c with the oxidation-resistant film 34b made of tungsten carbide around it, an increase in impedance can be suppressed. Furthermore, since the temperature is lower than or equal to the oxidation temperature of tungsten, an oxidization of the second rod member 34 can be prevented. The length x [cm] from the top end 42a to the predetermined position 33 of the rod 42 made of Ni is greater than or equal to 2 [cm] and less than or equal to 25 [cm] regardless of the length L [cm] of the rod 42 made of Ni.

The core member 34c is the tungsten core member and the oxidation-resistant film 34d is the tungsten carbide film. In this configuration, the second rod member 34 is manufactured relatively easily. In other words, it is relatively easy to form the oxidation-resistant film 34d made of tungsten carbide by carburizing or applying PVD or CVD around the tungsten core member. Since the hardness of tungsten carbide is higher than that of tungsten, the surface of the second rod member 34 is not easily scratched even if the number of times the second rod member 34 is inserted or removed from the socket 60 increase.

Furthermore, the thickness of the oxidation-resistant film 34d, that is the tungsten carbide film, is preferably greater than or equal to 0.1 μm and less than or equal to 5 μm. If the thickness of the tungsten carbide film is greater than or equal to 0.1 μm, oxidation and damage of the core member 34c, that is the tungsten core member, can be sufficiently prevented. Although the electrical resistivity of tungsten carbide is higher than that of tungsten, if the thickness of the tungsten carbide film is less than or equal to 5 μm, the tungsten carbide film does not significantly affect an electrical conductivity of the second rod member 34. If the thickness of the tungsten carbide film is greater than 5 μm, there is a risk that the tungsten carbide film will generate heat when the RF power increases.

Furthermore, it is highly worth applying the RF rod 30 to the wafer support table 20.

The present invention is not limited to the above-described embodiment and can be implemented in various forms without departing from the technical scope of the present invention.

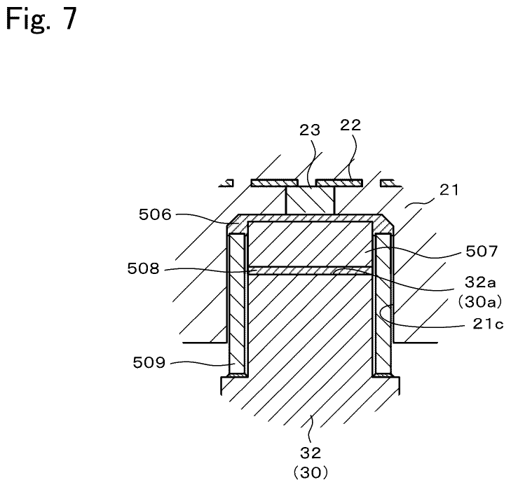

In the above-described embodiment, the top end 32a of the first rod member 32 of the RF rod 30 is connected to the conductive member 23 exposed to the bottom of the hole 21c, but the configuration is not limited to this. For example, the conductive member 23 may be eliminated, and the RF electrode 22 may be exposed to the bottom of the hole 21c, and the exposed RF electrode 22 and the top end 30a of the RF rod 30 (the top end 32a of the first rod member 32) may be joined to each other. Alternatively, as illustrated in FIG. 7, the conductive member 23 and the RF rod 30 may be connected to each other with a low-thermal expansion member 507 disposed in between. The low-thermal expansion member 507 is a conductor made of a material having a thermal expansion coefficient of at least less than or equal to 8.0×10⁻¹/° C. at 400° C. or below, such as molybdenum, tungsten, a molybdenum-tungsten alloy, a tungsten-copper-nickel alloy, or Kovar. In such a case, the hole 21c has a larger width than the top end 32a, and a cylindrical atmosphere-shielding member 509 is inserted in the hole 21c. The atmosphere-shielding member 509 may be made of pure nickel, a nickel-based heat-resistive alloy, gold, platinum, silver, or an alloy thereof. Furthermore, a small space is provided between the outer surface of the atmosphere-shielding member 509 and the inner surface of the hole 21c. Furthermore, the inner space of the atmosphere-shielding member 509 accommodates the low-thermal expansion member 507. The low-thermal expansion member 507 and the bottom of the hole 21c, and the low-thermal expansion member 507 and the conductive member 23, are joined to each other, respectively, with conductive joining layers 506 and 508, and the atmosphere-shielding member 509 and the bottom of the hole 21c are joined to each other with the conductive joining layer 506. The conductive bonding layers 506 and 508 may be Au—Ni brazing layers. In such a case, the conductive member 23 may be made of Ni, Mo, W, or Mo—W alloy.

In the above-described embodiment, the RF electrode 22 is in a mesh form but may be in another form. For example, a coil form, a planar form, or a perforated metal may be employed.

In the above-described embodiment, AlN is employed as a ceramic material, but the ceramic material is not limited to this. For example, alumina may be employed. In such a case, the RF electrode 22, the conductive member 23, and the heater electrode 27 are each preferably made of a material having a thermal expansion coefficient closer to that of the ceramic.

In the above-described embodiment, a DC voltage may be applied across the RF electrode 22 to attract the wafer W to the wafer placement surface 21a. The ceramic base 21 may further have an electrostatic electrode embedded therein, and a DC voltage may be applied across the electrostatic electrode to attract the wafer W to the wafer placement surface 21a.

In the above-described embodiment, the core member 34c is made of tungsten and the oxidation-resistant film 34d is made of tungsten carbide, but they are not limited to these. For example, the core member 34c may be made of molybdenum and the oxidation-resistant film 34d may be made of molybdenum carbide.

International Application No. PCT/JP2023/032112, filed on Sep. 1, 2023, is incorporated herein by reference in its entirety.

What is claimed is:

1. A wafer support table comprising:
a ceramic base having a wafer placement surface and including an RF electrode and a heater electrode embedded;
a hole extending from a surface of the ceramic base opposite the wafer placement surface toward the RF electrode; and
an RF rod through which radio-frequency power is supplied to the RF electrode and having a top end joined to the RF electrode exposed to a bottom of the hole or joined to a conductive member connected to the RF electrode, wherein
the RF rod is a hybrid rod including a first rod member that is made of Ni and constitutes a portion of the RF rod from the top end to a predetermined position located between the top end and a base end and a second rod member that is joined to the first rod member and constitutes a portion of the RF rod from the predetermined position to the base end, and
the second rod member is a non-magnetic core member with an oxidation-resistant film around the non-magnetic core member, and
the non-magnetic core member is a tungsten core member.

2. The wafer support table according to claim 1, wherein
the predetermined position is determined by using a rod made of Ni, instead of the hybrid rod, and is a position where T(x) represented by T(x)=Ts−(□T/L)*x is greater than or equal to Curie temperature of Ni and lower than or equal to oxidation temperature of the non-magnetic material, where Ts [° C.] is a temperature of the heater electrode (provided that Ts exceeds the Curie temperature of Ni), L [cm] is a length of the rod made of Ni, □T [° C.] is a difference in temperature between ends of the rod made of Ni, x [cm] is a length of the rod made of Ni from the top end to the predetermined position, and T(x) [° C.] is a temperature of the rod made of Ni at the predetermined position.

3. The wafer support table according to claim 1, wherein
the oxidation-resistant film is a tungsten carbide film.

4. The wafer support table according to claim 3, wherein
the thickness of the tungsten carbide film is greater than or equal to 0.1 μm and less than or equal to 5 μm.

5. An RF rod that is a hybrid rod comprising:
a first rod member that is made of Ni and constitutes a portion of the RF rod from a top end to a predetermined position located between the top end and a base end and a second rod member that is joined to the first rod member and constitutes a portion of the RF rod from the predetermined position to the base end, wherein
the second rod member is a non-magnetic core member with an oxidation-resistant film around the non-magnetic core member, and
the non-magnetic core member is a tungsten core member.
